(19) United States
(12) Patent Application Publication
(10) Pub. No.: US 2004/0105244 A1
(43) Pub. Date: Jun. 3, 2004

(54) Lead assemblies with offset portions and microelectronic assemblies with leads having offset portions

(76) Inventors: Ilyas Mohammed, Santa Clara, CA (US); Young-Gon Kim, Cupertino, CA (US)

Correspondence Address: LERNER, DAVID, LITTENBERG,, KRUMHOLZ & MENTLIK, 600 SOUTH AVENUE WEST, WESTFIELD, NJ, 07090, US

(21) Appl. No.: 10/635,169

(22) Filed: Aug. 6, 2003

Related U.S. Application Data
(60) Provisional application No. 60/401,395, filed on Aug. 6, 2002.

(51) Int. Cl. H05K 5/06; H01L 23/28; H05K 7/04

(52) U.S. Cl. 361/811; 29/832; 29/840; 29/827; 174/52.2; 257/E21.503

(57) ABSTRACT

A lead assembly including a connector connecting structure having a plurality of separable portions and a plurality of leads. Each of the leads defined that they have a first end, a second end, a lead axis defined by the first and the second end, and an offset portion disposed between the first end and the second end. The offset portion being offset from the lead axis and adapted to be displaced downwardly with respect to the lead axis and bonded to a contact. The leads are preferably integral with the connecting structure. The connecting structure may be arranged outwardly of the leads, or may include parts interdispersed between groups of leads. The groups of leads may or may not correspond to individual units incorporating a microelectronic element.

### CROSS-REFERENCE TO RELATED APPLICATIONS

This application claims the benefit of U.S. Provisional Application No. 60/401,395 filed on Aug. 6, 2002, the disclosure of which is incorporated by reference herein.

### BACKGROUND OF THE INVENTION

The present invention relates to lead assemblies with offset portions, to microelectronic assemblies with leads having offset portions, and methods of forming microelectronic assemblies.

Certain microelectronic components incorporate leads for forming connections to microelectronic elements. Lead frames are used in microelectronic components as a means to provide a plurality of fragile leads that are connected to one another for stability and to facilitate handling of the leads. In one example, a plurality of leads is arranged around a stabilizing ring. Each lead is attached to the stabilizing ring. The ring is later removed by tearing the ring away from the leads.

A component with leads having curved portions are disclosed in certain embodiments of U.S. Pat. No. 5,679,977, the disclosure of which is hereby incorporated by reference herein. The component includes a top layer of dielectric material and a compliant layer. Individual leads are disposed between the top layer and the compliant layer. The component has slots and the leads extend across the slots. The curved portions are disposed in the slots so that the curved portions may be engaged with a bonding tool and forced into engagement with contacts of a chip underlying the component.

Another component incorporating leads that are forced into engagement with the contacts of a chip is disclosed in certain embodiments of U.S. Pat. No. 5,915,752, the disclosure of which is hereby incorporated by reference herein. The component includes a gap and a plurality of leads extending across the gap. The leads have a securement section, a connection section, and a frangible section in-between the securement section and the connection section. The frangible section breaks when the connection section is forced into engagement with a contact, so that the lead breaks away from the securement section. The formation of the frangible section adds to the cost of the component and introduces a risk of damaging the leads. The connection section must be long enough to reach the contact disposed adjacent the gap. The distance between the leads and the contacts should be great enough to allow the lead to bend and to engage the contact. The standoff provided between the lead and the microelectronic element should accommodate the lead.

It would be desirable to provide a component having a plurality of leads with greater stability and that are easier to construct, with less cost, and less risk. It would also be desirable to construct an assembly requiring less standoff between the leads and the microelectronic element.

### SUMMARY OF THE INVENTION

In a first aspect of the present invention, a lead assembly comprises a connecting structure having a plurality of separable portions. The lead assembly has a plurality of leads having a first end, a second end, a lead axis defined by the first end and the second end, and an offset portion disposed between the first end and the second end. The offset portion is offset from the lead axis and adapted to be displaced downwardly with respect to a lead axis and bonded to a contact. Each lead is connected to the connecting structure and separable from the assembly by severing at least one separable portion. A lead assembly according to embodiments of the invention provides a plurality of leads that is conveniently incorporated into an assembly with a microelectronic element. The connecting structure interconnects a plurality of leads for forming one or more assemblies. Furthermore, certain methods of making the lead assembly require elements that are electrically connected to one another, such as in electroplating.

The leads are preferably integral with the connecting structure. The connecting structure may be arranged outwardly of the leads, or may include parts interspersed between groups of leads. The groups of leads may or may not correspond to individual units incorporating a microelectronic element.

The leads may have a variety of shapes. The present invention contemplates lead assemblies with groups of leads having configurations different from other groups of leads in the assembly. The offset portion is offset from the lead axis and generally disposed on one side of the lead axis. The offset portion desirably includes a middle portion extending in a direction generally parallel to the lead axis. The offset portion desirably includes a first curved part between the first end and the middle portion and a second curved part between the middle portion and the second end. The offset portion may comprise any shape. The offset portion, for example, may comprise at least one straight side.

In certain preferred embodiments, the at least one separable portion extends in a direction generally parallel to the lead axis. The connecting structure may include a bus element interconnecting the separable portions. In certain preferred embodiments, the bus element comprises an elongate element extending transversely to the lead axis, and the separable portions are attached to the bus element and are spaced from one another along the bus element. Each separable portion is connected to the first end of one of the leads. Each separable portion extends generally in the same direction as the lead axis. The bus element interconnects the leads of the assembly. A separable portion is desirably disposed between each lead and the bus element and desirably comprises a breakable portion arranged so that each lead may be released from its connection to the other leads.

The first end desirably has a first width, and the separable portion connected to the first end desirably has a second width, which is less than the first width for the first end. The separable portions provide a desirable area on the lead assembly for severing the connection of a lead from the other leads of the assembly.

In certain preferred embodiments, the separable portions extend transversely to the lead axis. Each separable portion interconnects adjacent leads. Each separable portion is connected to the first end of one of the leads.

In a further aspect of the present invention, a microelectronic component comprises a dielectric layer having a slot defined therein and a lead assembly overlies the dielectric layer. The lead assembly comprises a plurality of leads having an offset portion disposed between a first end and a second end. The offset portion is offset from a lead axis defined by the first end and the second end. A connecting structure is connected to the first ends of the leads and interconnects the leads. The lead assembly overlies the dielectric layer so that each offset portion is aligned with the slot.

The webs desirably comprise portions for isolating the leads from the lead assembly. The dielectric layer is desirably constructed to allow access to the webs. In certain preferred embodiments, the dielectric layer has a plurality of apertures, each of the apertures being disposed in alignment with at least one of the webs. In other preferred embodiments, the dielectric layer has a window aligned with the webs. In still further embodiments, the slot comprises an elongate slot and the slot is aligned with the webs, as well as the offset portions. The dielectric layer and the lead assembly may be arranged so that the first ends of the leads are disposed at a first edge of the slot and the second ends are disposed at a second edge of the slot. In such arrangements, the elongate slot may extend transversely to the lead axis.

In certain preferred embodiments, the offset portion comprises a middle portion disposed between the first end and the second end. The middle portion extends in a direction generally parallel to the lead axis. The offset portion may have a first curved part between the first end and the middle portion and a second curved part between the middle portion and the second end. The offset portion may comprise at least one straight side.

In another aspect of the present invention, a method of forming a microelectronic assembly comprises providing a microelectronic component including a dielectric layer having a slot defined therein and a lead assembly overlying the dielectric layer. The lead assembly comprises a plurality of leads having an offset portion between a first end and a second end. The offset portion is offset from a lead axis defined by the first end and the second end. A connecting structure is connected to the first ends of the leads and includes at least one separable portion interconnecting at least some of the leads. The lead assembly overlies the dielectric layer so that each offset portion is aligned with the slot. The microelectronic component includes at least one aperture providing access to the at least one separable portion. The microelectronic component is assembled with a microelectronic element so that a first face of the microelectronic element faces the microelectronic component. The offset portion of one of the leads is connected to one of a plurality of contacts exposed at the first face. The connecting structure is severed at the at least one separable portion so as to isolate from the lead assembly the lead connected to the contact. In certain preferred embodiments, the at least one separable portion comprises a plurality of webs interconnecting the leads.

The step of connecting includes forcing the offset portion toward one of the contacts. In certain preferred embodiments, the offset portions of a plurality of the leads are forced toward the contacts concurrently. Each offset portion is desirably forced in a direction toward the first face and toward the lead axis. The first end and second end may be twisted as the offset portion is forced toward the contact.

The webs desirably comprise separable portions for isolating the leads from the lead assembly. The step of severing may comprise advancing a tool carrying a blade into the at least one aperture to cut one of the webs. In certain preferred embodiments, the step of severing comprises using a tool carrying a plurality of blades to cut a plurality of the webs concurrently.

The step of assembling desirably comprises arranging the microelectronic element and the microelectronic component so that each contact is disposed between the first end and the second end, along the lead axis.

A flowable material is desirably introduced into the slot, so as to surround the offset portion and the contact, after the step of bonding. In certain preferred embodiments, the step of assembling comprises disposing at least one dielectric mass between the dielectric layer and the microelectronic element before the step of connecting. The at least one dielectric mass may be arranged to provide a standoff distance between the contacts and the leads. The leads desirably have a length between the first end and the second end sufficient to span the standoff distance after the step of connecting.

### BRIEF DESCRIPTION OF THE DRAWINGS

These and other features, aspects, and advantages of the present invention will become better understood with regard to the following description, appended claims and accompanying drawings where:

FIG. 1 is a partial plan view of a microelectronic component arranged with a microelectronic element in a method in accordance with an embodiment of the invention;

FIG. 2 is a partial cross-sectional view of an assembly in a method in accordance with the embodiment of FIG. 1;

FIG. 3 is a partial cross-sectional view of the assembly of FIG. 2, at a later stage in a method in accordance with the embodiment of FIGS. 1-2;

FIG. 4 is a partial plan view of an assembly in a method in accordance with another embodiment of the invention;

FIG. 5 is a partial cross-sectional view of an assembly in a method in accordance with the embodiment of FIG. 4;

FIG. 6 is a partial cross-sectional view of the assembly of FIG. 5, at a later stage in a method in accordance with the embodiment of FIGS. 4-5;

FIG. 7 is a partial plan view of a lead assembly in accordance with a further embodiment of the invention;

FIG. 8 is a partial cross-sectional view of an assembly in a method in accordance with the embodiment of FIG. 7;

FIG. 9 is a partial cross-sectional view of the assembly of FIG. 8, at a later stage in a method in accordance with the embodiment of FIGS. 7-8;

FIG. 10 is a plan view of a microelectronic assembly in accordance with another embodiment of the invention;

FIG. 11 is a partial plan view of a microelectronic component in accordance with yet another embodiment of the invention;

FIG. 12 is a partial plan view of a microelectronic component in accordance with a further embodiment of the invention;

FIG. 13 is a partial cross-sectional view of the component of FIG. 11 at a later stage in a method in accordance with the embodiment of FIG. 11;

FIG. 14A is a partial plan view of a lead in accordance with a further embodiment of the invention;

FIG. 14B is a partial plan view of a lead in accordance with another embodiment of the invention;

FIG. 14C is a partial plan view of a lead in accordance with another embodiment of the invention;

FIG. 14D is a partial plan view of a lead in a further embodiment of the present invention;

FIG. 15 is a partial cross-sectional view of a microelectronic assembly in accordance with further embodiments of the invention;

FIG. 16 is a partial plan view of a method in accordance with yet another embodiment of the present invention;

FIG. 17 is a partial plan view of a microelectronic component arranged with a microelectronic element in a method in accordance with yet another embodiment of the invention;

FIG. 18 is a partial plan view of a microelectronic component arranged with a microelectronic element in a method in accordance with a further embodiment of the invention; and

FIG. 19 is a partial cross-sectional view of a microelectronic component arranged with a microelectronic element in a method in accordance with the embodiment of FIG. 18.

### DETAILED DESCRIPTION

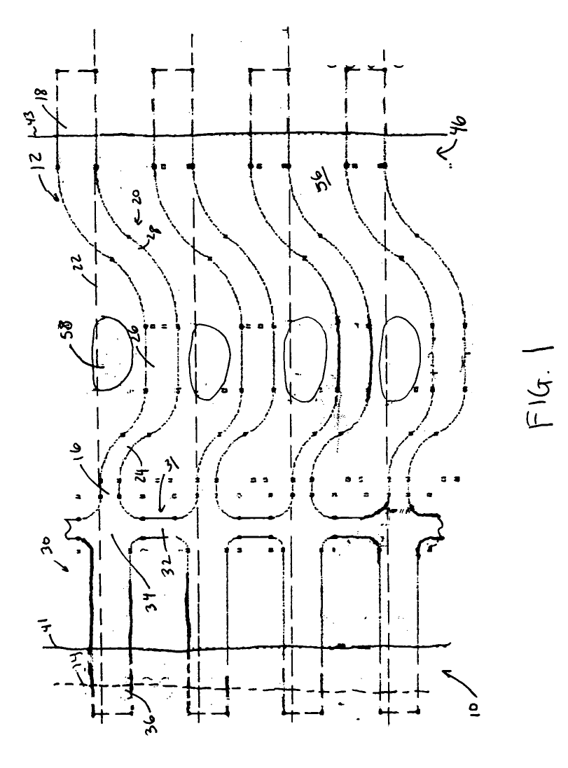

One embodiment of the present invention is shown in FIGS. 1-3. As shown in FIG. 1, a lead assembly 10 comprises a plurality of leads 12 spaced along a first axis 14. Each lead extends generally transversely to the first axis 14. Each lead comprises a first end 16, a second end 18 and an offset portion 20 disposed between the first end 16 and the second end 18. The first end and the second end may comprise elongate portions of the lead, defining a lead axis 22 which is transverse to the first axis 14. The offset portion 20 is offset from the lead axis 22. The lead axis 22 comprises an axis that passes through a point on the first end and a point on the second end.

The offset portion 20 includes a first curved part 24 extending from the first end 16 to a middle portion 26. The middle portion 26 comprises an elongate portion of the lead extending generally parallel to the lead axis 22 but offset therefrom. A second curved part 28 extends from the middle portion 26 to the second end 18. The first end extends generally along the lead axis 22 to the first curved part 24. The first curved part 24 curves generally away from the lead axis 22 and meets the middle portion 26, which is offset from the lead axis 22. The second curved part 28 curves generally toward the lead axis 22 and meets with the second end 18. The second end 18 extends generally along the lead axis 22.

The first end 16 and second end 18 may or may not be centered on the lead axis 22 and may or may not be aligned with one another. In certain preferred embodiments, the first end 16 is disposed on one side of the lead axis 22 and the second end 18 is disposed on the other side of the lead axis 22, as shown in FIG. 1. This offset configuration may be desired, depending upon the spacing, size and shape of the leads. The leads 12 may comprise any conductive material used for conductors in microelectronic devices or assemblies, such as gold or copper. Each part of the lead 12 is preferably integral with the other parts.

The leads 12 are connected to a connecting structure 30, which is preferably formed integrally with the leads. The connecting structure 30 includes a plurality of separable portions 31 for isolating the leads from the lead assembly, as discussed further below. The separable portions may comprise webs 32 interconnecting the leads 12 with one another. The connecting structure 30 has a plurality of webs 32 attached to the leads, on either side of each lead, so as to interconnect the leads 12. In the embodiment shown in FIG. 1, the webs 32 and leads 12 are connected at junctions 34 so that the webs 32 extend in a direction transverse to the lead axis 22. The connecting structure may also include an extension 36 for each lead 12, which extends in the same general direction as the first end 16 of the lead 12. Each extension is attached to a first end 16 at a junction 34, on the opposite side of the junction from the lead 12. The extension 36 generally extends along the lead axis 22, whereas the webs 32 interconnect the leads 12 to one another so that the leads have a side-by-side arrangement.

In certain preferred embodiments, a lead assembly is used in a method of forming a microelectronic assembly. A lead assembly as shown in FIG. 1 may be incorporated in a microelectronic component, as shown in FIGS. 1-3. The microelectronic component 40 comprises a top layer 42, which desirably comprises a sheet of dielectric material and a bottom layer 44, which also desirably comprises a dielectric material. The component 40 includes a slot 46 that extends through the top layer 42 and the bottom layer 44. The lead assembly 10 is attached to the component 40 so that the lead assembly 10 is disposed between the top layer 42 and the bottom layer 44. The slot 46 has an elongated shape that extends along the first axis 14, transversely to the lead axis 22. The slot 46 encompasses the offset portion 20 of the leads 12 and part of the connecting structure 30. As shown in FIG. 1, the lead assembly 10 is arranged with the top layer and bottom layer so that the webs 32 and the curved portion 20 are aligned with the slot 46. The extension 36 and the second ends 18 are secured between the top layer 42 and bottom layer 44. The component 40 desirably includes vias 48 that extend through the top layer 42 and are aligned with terminals 50. The terminals are attached to each lead at the extension 36 or the second end 18 and the terminals may be formed integrally with the leads. A via 48 in the top layer 42 permits access to the terminal 50. The microelectronic component is preferably arranged and made as disclosed in certain embodiments of U.S. Pat. No. 5,679,977, the disclosure of which is hereby incorporated by reference herein.

The microelectronic component 40 may be formed using conventional methods known in the art. The lead assembly 10 may be formed in place on the top layer 42. For example, a copper sheet, or a sheet of another conductive material, is laminated onto a sheet of dielectric material. The copper sheet is covered with a photoresist pattern and etched to form the leads having offset portions, a connecting structure, and preferably terminals. The slot may be formed, as well as vias for terminals, using selective application of radiant energy. For example, a laser may be used. Alternatively, mechanical punching may be used to form the lead assembly or sheet.

The bottom layer 44 is desirably formed using a plurality of dielectric elements 52 and may be formed as the component 40 is assembled with a microelectronic element 54 having contacts 58 exposed at a first face 56. The dielectric elements 52 are provided between the top layer 42 and the microelectronic element 54 to support the top layer 42 above the first face. The dielectric elements provide standoff between the leads 12 and the contacts 58. A liquid composition is stenciled onto the surface of the top layer 42 that carries the lead frame 10. The liquid composition may comprise an elastomer. Stenciling, as is known in the art, leaves masses of the liquid composition on the top layer 42. The masses are either fully or partially cured to form the dielectric elements 52. The first face of the microelectronic element 54 is pressed against the dielectric elements 52 and partially cured elastomer, or an adhesive applied to the dielectric elements, to hold the top layer on the microelectronic element 54. The height of the dielectric elements 52 is desirably uniform. The dielectric elements 52 define channels between adjacent dielectric elements 52. Preferably, one of the elements 52 is located adjacent the first edge 41 and another element 52 is located adjacent the second edge 43 to support the lead assembly and to facilitate bonding the lead to the contact. The dielectric elements 52 may be formed using any of the materials and methods disclosed in U.S. Pat. Nos. 5,659,952, 5,706,174; and 6,169,328, the disclosures of which are hereby incorporated by reference herein.

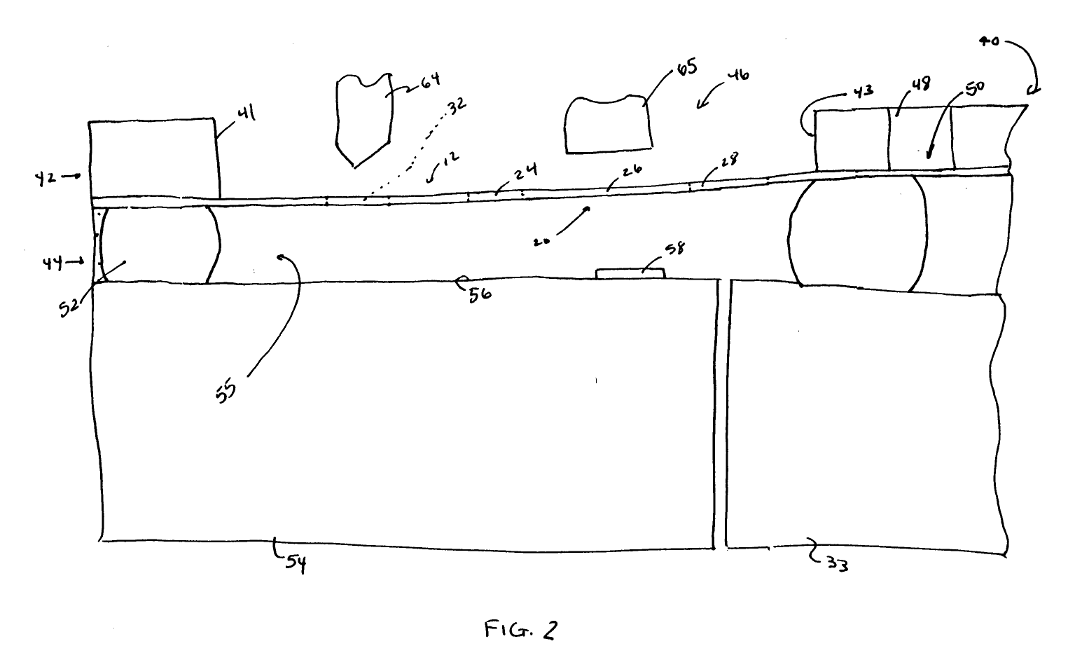

In certain embodiments, the leads 20 are arranged so that the second end 18 or first end 16 extends to a terminal 50 located beyond the peripheral edges of the microelectronic element 54. A support 33 is desirably included to support the top layer 42 and lead assembly 10 at the outer portions of the lead assembly as shown in FIG. 2.

The dielectric elements 52, also known as “nubbins,” are not required. The microelectronic component 40 may comprise a top layer 42 of dielectric material overlying a unitary bottom layer 44. The bottom layer 44 may comprise a liquid composition applied to the top layer and cured or a sheet of dielectric material adhered to the top layer.

After the microelectronic component 40 and microelectronic element 54 are positioned with respect to one another, the leads are then connected to the contacts. At this stage, the leads are supported over the first face 56. The leads 12 are bonded to the contacts 58 by engaging the middle portions 26 with a tool 65 and displacing the middle portion 26 toward a corresponding contact 58. The tool 65 may comprise an ultrasonic or thermosonic bonding tool. Ultrasonic energy, heat, or a combination thereof is applied to the middle portion 26 and the contact 58 so as to bond the middle portion to the contact. The tool may include robotic control or computerized control hardware for controlling the movement of the middle portions 26 of the leads. However, such control is not essential. In forcing the middle portion 26 toward the contact 58, the middle portion 26 moves toward first face 56, and toward the lead axis 22. In moving the middle portion, the middle portion travels in a path generally around the lead axis 22. In certain embodiments, the middle portion 26 may move only a very small distance toward the lead axis 22. The component of movement toward the lead axis 22 may be very small, negligibly small, or almost zero.

In certain preferred embodiments, the leads are generally shaped with the widest dimension in the plane of the lead assembly 10. After bonding, the middle portion 26 remains in a plane generally parallel to the plane of the lead assembly 10 and first face 56. The first curved part 24 and second curved part 28 are twisted out of the plane of the lead assembly 10, as best seen in FIG. 3. The first curved part 24 and second curved part 28 are disposed in a plane transverse to the plane of the lead assembly 10 after the middle portion 26 is bonded with the contacts 58. Preferably, the middle portions 26 of a plurality of the leads 12 are engaged by a gang-bonding device that bonds the middle portions 26 of each lead to a corresponding contact 58 concurrently.

The shape and dimensions of the lead 12 are sufficient to span the gap 55 between the lead 12 and the contact 58 on the first face 56. The offset portion 20 has a sufficient length overall to bend down from the first end 16, bend to the contact 58, and bend upwardly to meet the second end 18.

Before or after the step of bonding, the webs 32 interconnecting each of the leads 12 are severed so as to isolate each of the leads 12. A cutting blade 64 is introduced into the slot 46 and is used to sever each of the webs 32. (See FIG. 2) Preferably, a tool incorporating a number of such blades is used to sever each of the webs 32 concurrently. A portion of each web may remain after the severing step, but the cut edges of the webs should not remain in contact or closely adjacent to one another.

After bonding, a flowable material is introduced so as to surround the leads and the connection 62 between the middle portion 26 and contact 58. In embodiments incorporating a plurality of dielectric elements 52, the bottom layer 44 is completed by introducing the flowable material 60 between the top layer 42 and the microelectronic element 54. The flowable material is introduced so that the flowable material 60 is disposed in the channels in-between the dielectric elements 52 and so that the flowable material surrounds the connection 62 between the middle portion 26 and the contacts 58. The introduction of the flowable material 60 completes the formation of the bottom layer 44 for the component 40. The flowable material 60 preferably fills the slot 46. Preferably, a sheet is applied over the top layer 42, extending over the slot 46, so as to contain the flowable material 60. The flowable material may comprise a dielectric capsulant and conventional encapsulation techniques may be used. For example, the material 60 may be introduced under pressure and then cured. The component and element may be disposed in a mold, which may limit the flow of material 60.

In certain preferred embodiments, the microelectronic component comprises a flexible top layer formed by a thin sheet of material with a relatively high elastic modulus and a bottom layer comprising a compliant material, as disclosed in certain embodiments of U.S. Pat. No. 5,679,977, the disclosure of which is hereby incorporated by reference herewith. The flowable material 60 introduced into the channels between the dielectric elements 52 may comprise a compliant material or a material that is compliant after it is cured.

In certain embodiments of the invention, the connecting structure comprises webs having a thickness less than the thickness of the leads and/or remaining connecting structure. In other embodiments, the webs may comprise a portion having a notch formed therein. The notch may reduce the thickness or width of the web portion.

Methods according to embodiments of the present invention include assembling a microelectronic element incorporating a plurality of semiconductor chips, such as a wafer, with a microelectronic component having regions corresponding to each chip. The regions may carry a discrete lead assembly corresponding to a single chip or the microelectronic component may carry a pattern of leads that are interconnected and incorporate groups of leads corresponding to each chip. In addition, further embodiments comprise a microelectronic component having regions each corresponding to a semiconductor chip and individual chips may be assembled with such component. For example, the microelectronic component may comprise a strip and certain conventional TAB processing techniques may be used to assemble a plurality of semiconductor chips with the strip. In embodiments utilizing a microelectronic component for assembly with a plurality of semiconductor chips, the assembly is typically severed into units having a single chip and an individual component. Conventional dicing techniques may be used. In certain preferred embodiments, the step of severing the webs that interconnect the leads includes separating the assembly into individual units.

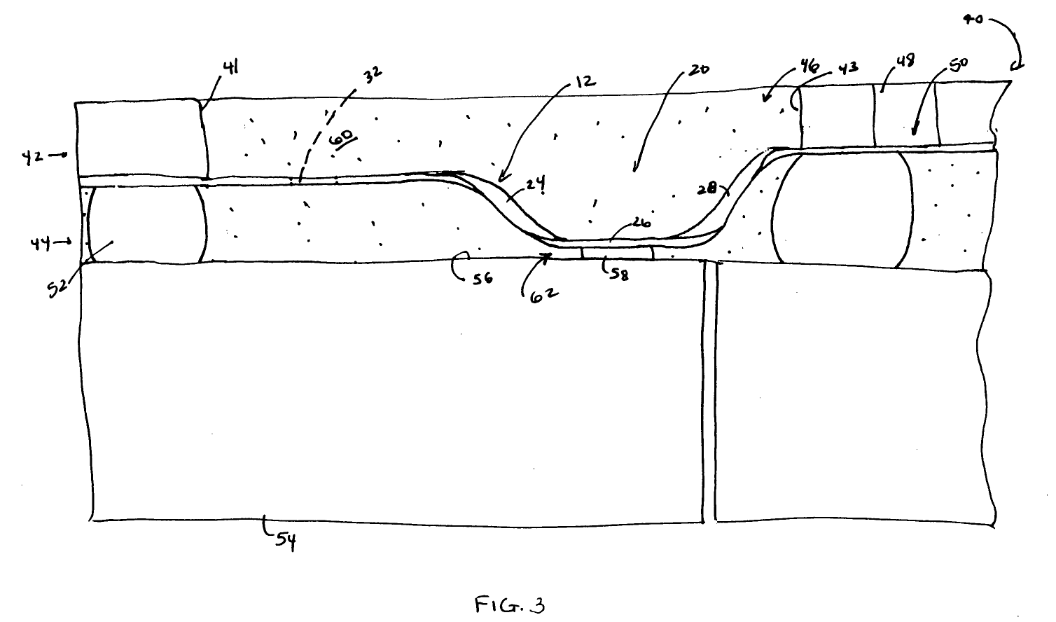

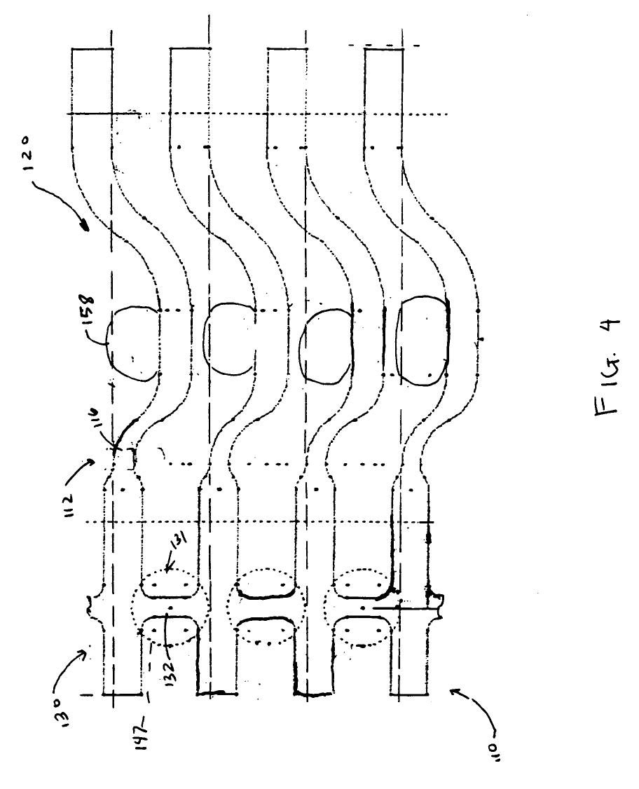

In another embodiment shown in FIGS. 4-6, a lead assembly 110 comprises a plurality of leads 112 having offset portions 120, similar to the offset portions 20 discussed above. The leads 112 have a first end 116 attached to a connecting structure 130. The connecting structure 130 includes a plurality of separable portions 131 for isolating the leads from the lead assembly. The separable portions may comprise webs 132, similar to the webs 32 discussed above. The lead assembly 110 is used in a microelectronic component 140 having a slot 146 and a plurality of apertures 147. Each of the apertures 147 is disposed in alignment with a web 132. After the microelectronic component 140 is assembled with a microelectronic element 154 and the offset portions 120 are bonded to the contacts 158, the webs 132 are severed by cutting each web 142 with a cutting blade 164. A flowable material 160 is introduced into the slot 146 and encapsulates the leads 120 and connections 162. The flowable material 160 may also be disposed in the apertures 147.

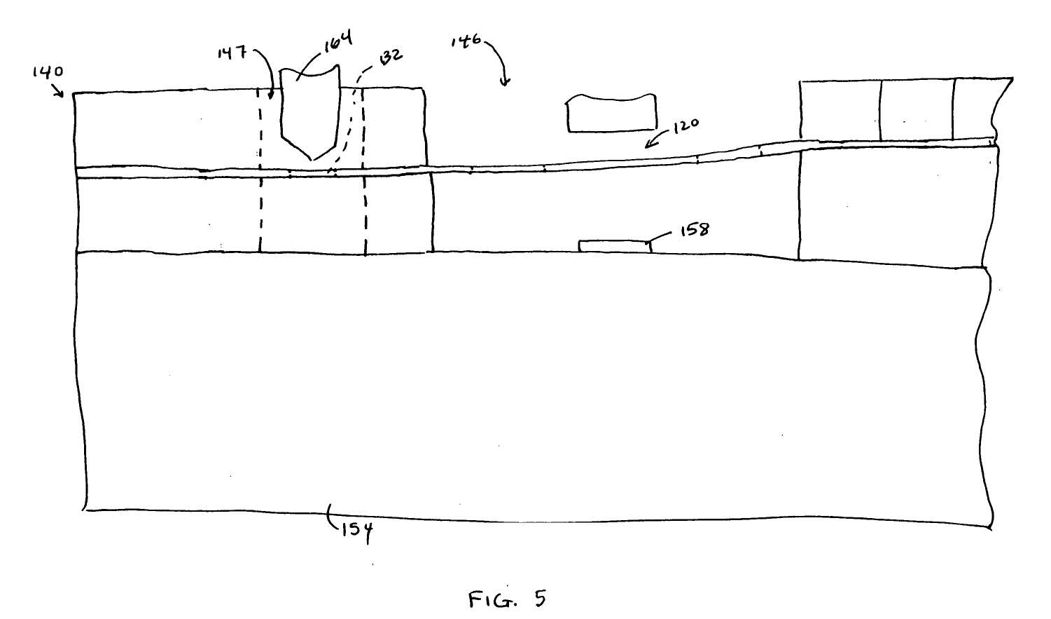

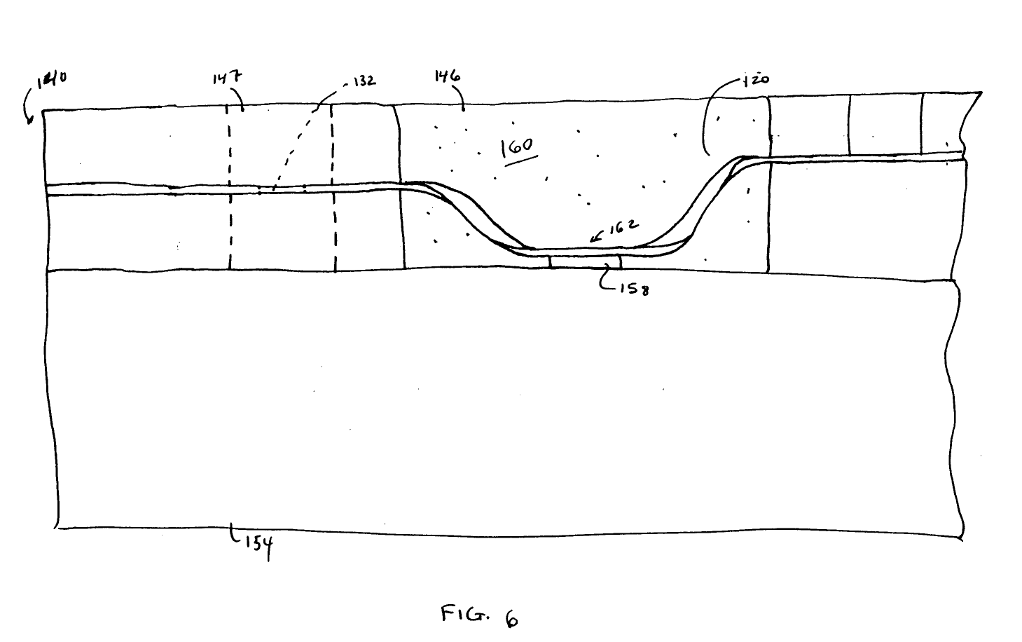

In a further embodiment of the invention, as shown in FIGS. 7-9, a lead assembly 210 incorporates a plurality of leads 212 that extend generally along a lead axis 222 and include offset portions 220 offset from the lead axis. The lead assembly 210 includes a connecting structure 230 attached to each of the first ends 216 of the leads 212. The connecting structure 230 includes separable portions 231 for isolating the leads from the lead assembly. The separable portions may comprise webs arranged so that a web 232 attached to each of the first ends 216. The first ends 216 and webs 232 extend in the same general direction as the lead axis 222. An extension 234 may be attached to each web 232 and each first end 216 so that the first end 216, extension 234 and web 232 all extend in the same general direction. The web 232 has a thickness “t” that is less than the thickness “T” of the extension 234. Each of the leads 212 is attached to one another in the assembly 210 by a bus 235. Each of the webs 232 are attached to the bus 235. The bus extends along a bus axis 214, which extends transversely to the lead axis 222.

The lead assembly 210 is used in a microelectronic component 240 having an elongate slot 246 and an elongated window 245. The window 245 extends in a direction parallel to the bus axis 214 and each of the webs 232 are aligned with the window 245. After the microelectronic component 240 is assembled with the microelectronic element 254, and offset portions 220 are bonded to contacts 258, each of the webs 232 are severed so as to isolate each of the leads 212 from one another and from the bus 235. A flowable material 260 is preferably disposed in the slot 246 and may also be disposed in the window 245. In other embodiments, the bus 235 is attached to extensions 234 extending in the same general direction as the first ends 216, whereas webs 232 extending in a direction transverse to the lead axis 222 interconnect the leads 212. In other embodiments, the webs 232 are aligned with the slot 246, which provides access to the webs 232 and the window 245 is omitted. In further embodiments, the component 240 has a plurality of apertures, each of which is aligned with a web 232.

In certain preferred embodiments, the microelectronic component includes a securement element adjacent the microelectronic element. The securement element supports outboard portions of the leads that extend beyond the peripheral edges of the microelectronic element. The outboard portions may be connected to terminals that are located beyond the peripheral edges of the microelectronic element in a “fan-out” arrangement. The securement element comprises materials similar to the microelectronic component and portions of the securement element may be formed integrally with the component. The leads having the outboard portion may include offset portions disposed within the slot in the microelectronic component and may be bonded to the microelectronic element as discussed above. In other preferred embodiments, the leads are connected to terminals which overlie the first face of the microelectronic element. These leads may incorporate offset portions that are bonded to the contacts of the microelectronic element as discussed above in a “fan-in” arrangement. Other embodiments include both fan-in and fan-out leads. The microelectronic element may comprise contacts exposed adjacent one or more of the peripheral edges of the first face, or contacts exposed at a central region of the first face. The contacts may be arranged in a row, a plurality of rows or any other configuration.

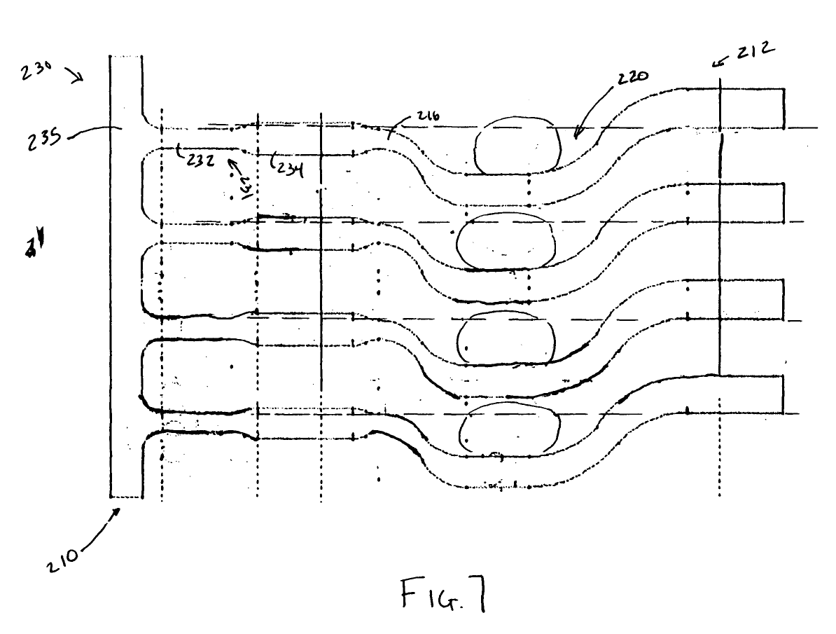

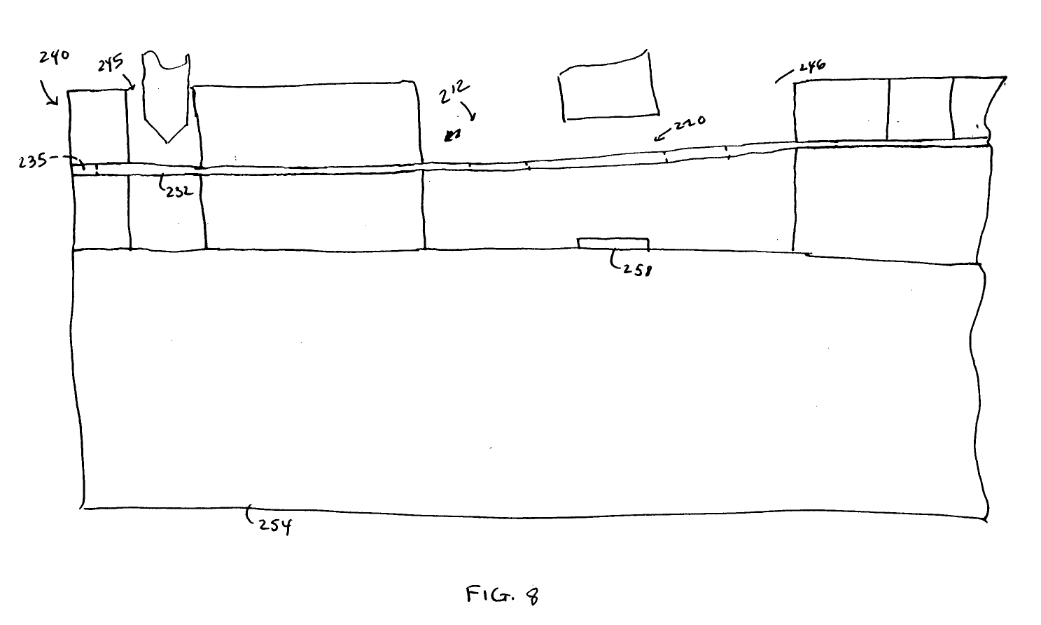

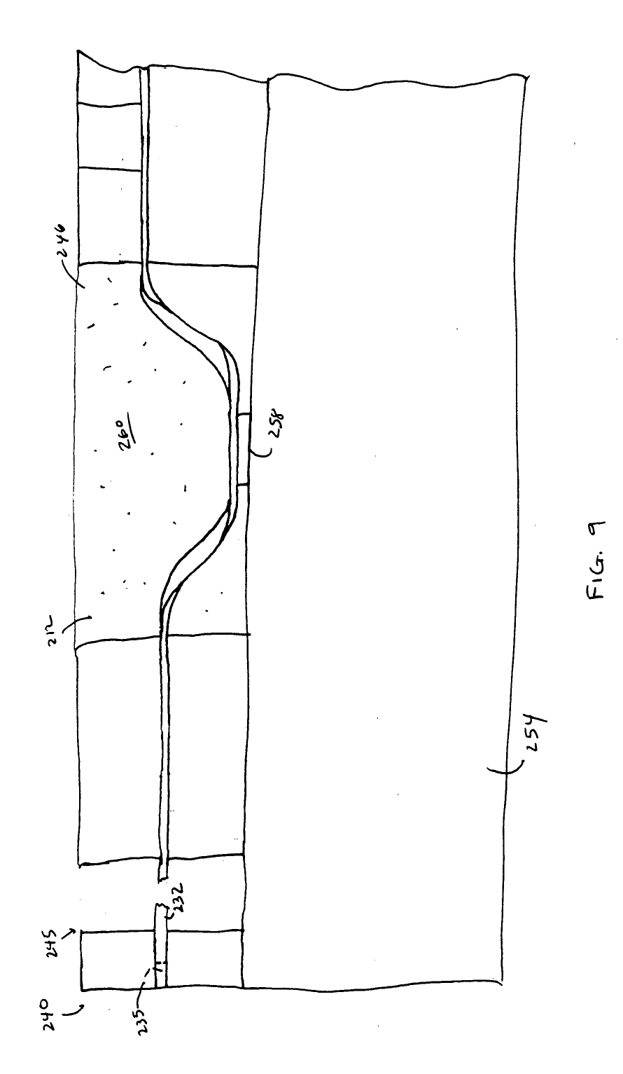

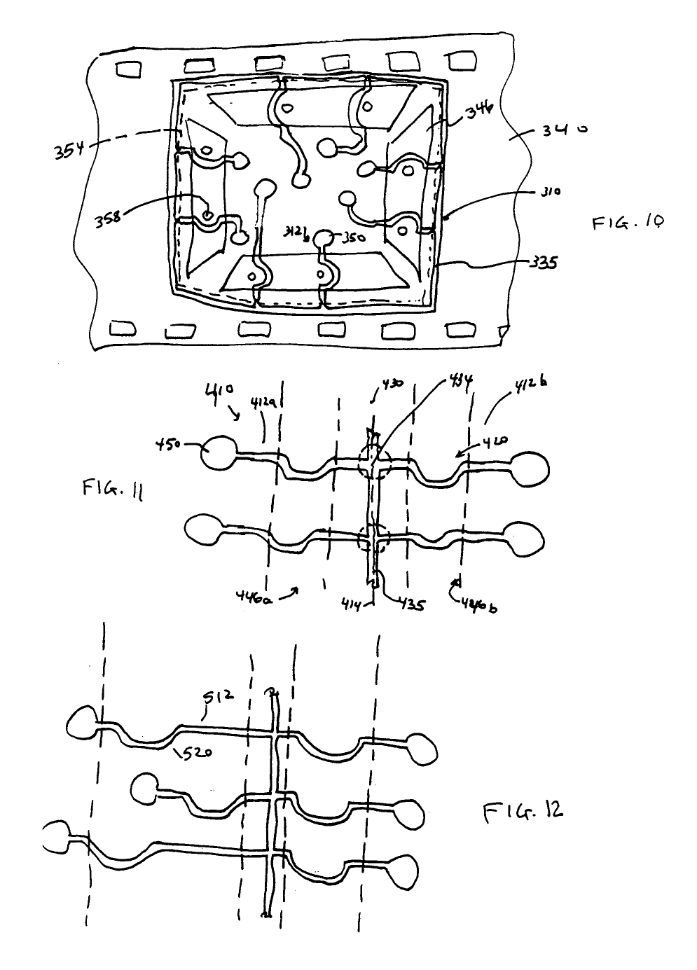

In certain preferred embodiments, the microelectronic component comprises a tape 340, as shown in FIG. 10. The tape 340 may comprise a plurality of slots 346 arranged so that when the microelectronic element 354 is assembled with the tape 340, contacts 358 arranged at the periphery of the first face of the microelectronic element 354 are aligned with the slots 346. The lead assembly 310 may incorporate a plurality of leads 312 that extend inwardly toward the microelectronic element 354 from a bus 335. Each of the leads 312 terminate in a terminal 350 that overlies the first face of the microelectronic element 354. In other embodiments, at least some of the leads terminate in a terminal disposed outwardly of the microelectronic element.

In further embodiments, the lead assembly incorporates leads that extend from the connecting structure in more than one direction. As shown in FIG. 11, the lead assembly 410 comprises a connecting structure 430 including a bus 435 extending along a bus axis 414. A lead 412a is connected to one side of the bus 435 and another lead 412b is connected to the other side of the bus 435 at a junction 434. Each of the leads include an offset portion 420 that is disposed in alignment with a slot 446 in the microelectronic component 440. Each of the leads 412 end in a terminal 450. The microelectronic component 440 may include a single slot encompassing the offset portions 420 for all of the leads. In other embodiments, the microelectronic component 440 has a first slot 446a encompassing the offset portions 420 for the leads on a first side of the bus 435 and a second slot 446b encompassing the offset portion 420 for the leads on the other side of the bus 435. FIG. 13 shows apertures 447 in alignment with the junctions 434, which are severed so as to isolate the leads. As shown in FIG. 12, each of the leads 512 may have offset portions 520 that are not in alignment with the offset portions of the other leads.

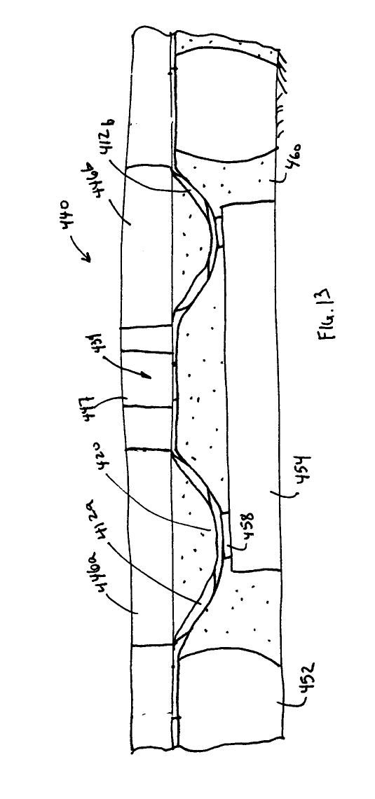

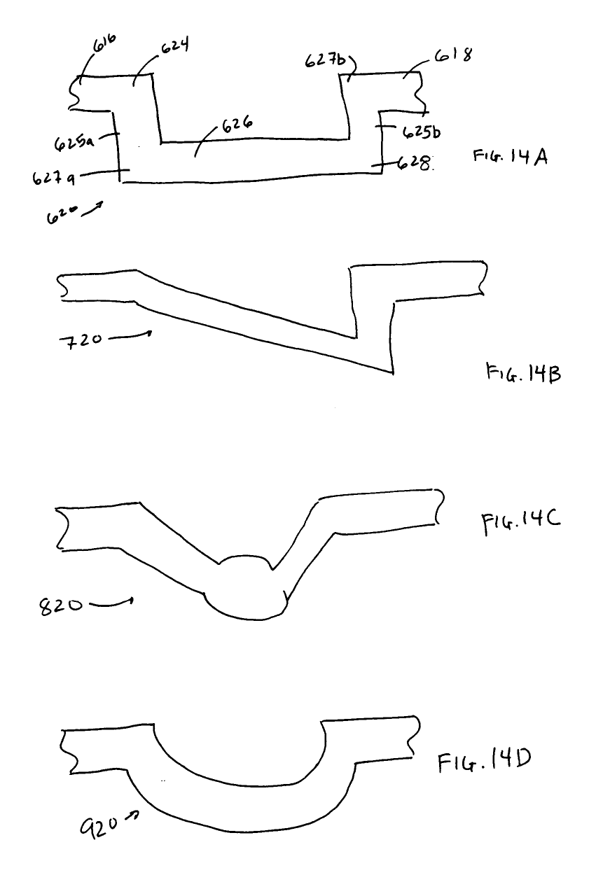

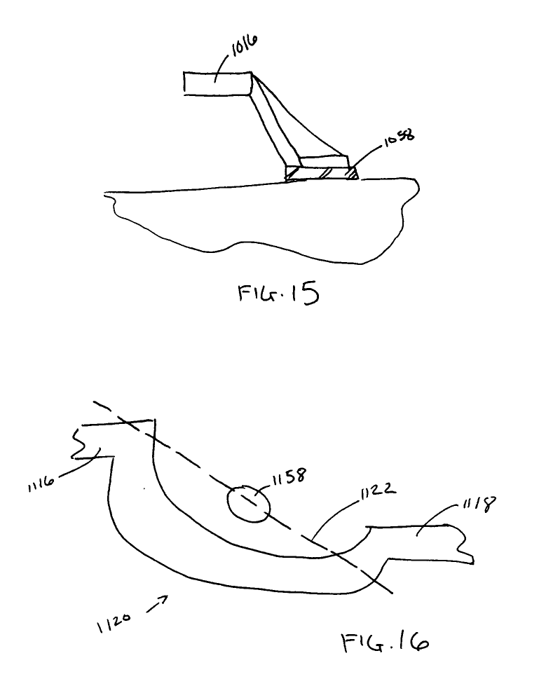

The offset portions may comprise curved portions of the leads, such as the U-shaped offset portions 20 shown in FIG. 1. In other embodiments, the leads comprise U-shaped portions 620 having an angled part 624 between a first end 616 and a side 625a, another angled part 627a between the side 625a and a middle portion 626. The middle portion 626 is connected to a second side 625b by a second angled part 628. The second side 625b is connected to the second end 618 by a fourth angled part 627b. (FIG. 14A) Offset portions comprising a triangular portion 720 (FIG. 14B), a V-shaped portion 820 (FIG. 14C), and a circular-shaped portion 920 (FIG. 14D) may be used. The offset portions are desirably bonded to contacts aligned with the lead axis and may be bonded to contacts 1058 that are aligned with the first end or second end or slightly out of alignment with the first end 1016 or second end, as shown in FIG. 15. As illustrated in FIG. 16, the lead axis 1122 may be transverse to the first end 1116 and second end 1118. The offset portion 1120 is engaged and moved toward contact 1158 and lead axis 1122 during bonding.

In certain preferred embodiments, as shown in FIG. 17, a microelectronic component and lead assembly is assembled with a microelectronic element having contacts exposed at a central region of the first face. For example, the contacts on the microelectronic element may be arranged in a single row or a pair of rows in a center region of the first face. As shown in FIG. 17, the offset portions 1220 are disposed so as to be in alignment with a contact from a single row when the component and the microelectronic element are arranged with one another. The middle portions of the leads are bonded to the contacts on the microelectronic element. The dielectric layer may comprise a slot 1246 aligned with the offset portions 1220 and apertures 1247 aligned with separable portions 1231 located between the offset portion 1220 and bus elements 1235a and 1235b. The connecting structure and apertures in the component may have other configurations discussed above.

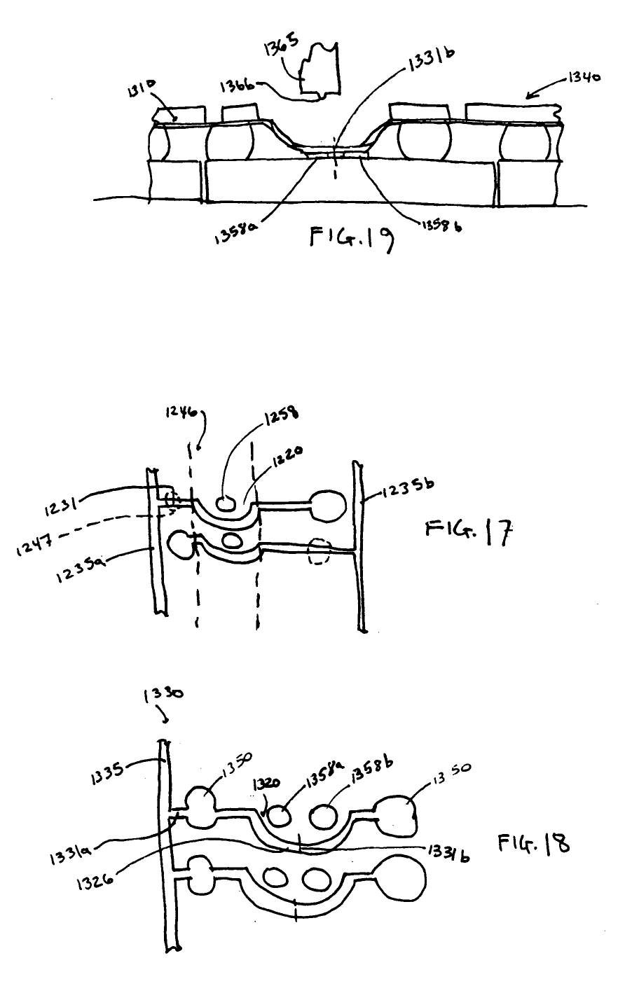

As shown in FIGS. 18 and 19, certain embodiments include assembling a component 1340 and lead assembly 1310 with a microelectronic element having contacts 1358 arranged in two rows in a central area of the first face. For example, the component carrying the lead assembly may include a single bus 1335 arranged outwardly of the leads.

Each offset portion 1320 is bonded to a pair of contacts 1358a and 1358b. A first separable portion 1331a is broken to isolate the lead from the connecting structure 1330 and a second separable portion 1331b is disposed on the middle portion 1326. In certain preferred embodiments, the tool 1365 for bonding the offset portion 1320 also carries a punch or a small blade 1366 for severing the second separable portion 1331b. Each end of the lead preferably terminates in a terminal 1350. For microelectronic elements having contacts with certain arrangements, an embodiment like that shown in FIGS. 18 and 19 is desirable.

In other preferred embodiments, no standoff is provided between the lead assembly and the microelectronic element. Thus, the middle portion of the leads may be only slightly displaced or not displaced at all in the direction toward the first face of the microelectronic element, during bonding to contacts on a microelectronic element.

Although the invention herein has been described with reference to particular embodiments, it is to be understood that these embodiments are merely illustrative of the principles and applications of the present invention. In other preferred embodiments, the lead assembly includes leads that have a first end and a second end that are aligned with one another on the lead axis. In addition, the invention may be used in components and assemblies other than those shown. Shapes for the offset portion other than those shown, that are arranged to traverse the gap between the lead assembly and microelectronic element can be used. It is therefore to be understood that numerous modifications may be made to the illustrative embodiments and that other arrangements may be devised without departing from the spirit and scope of the present invention as defined by the appended claims.

1. A lead assembly comprising:
a connecting structure having a plurality of separable portions;
a plurality of leads, each said lead having a first end, a second end, a lead axis defined by said first end and said second end, and an offset portion disposed between said first end and said second end;
said offset portion being offset from said lead axis and adapted to be displaced downwardly with respect to a lead axis and bonded to a contact; and
each lead being connected to said connecting structure and separable from the assembly by severing at least one of said separable portions.

2. The assembly according to claim 1, wherein said leads are integral with said connecting structure.

3. The assembly according to claim 2, wherein said connecting structure is arranged outwardly of said leads.

4. The assembly according to claim 1, wherein said offset portion is offset from said lead axis and generally disposed on one side of said lead axis.

5. The assembly according to claim 1, wherein said offset portion has a middle portion, said middle portion extending in a direction generally parallel to said lead axis.

6. The assembly according to claim 5, wherein said offset portion has a first curved part, said first curved part located between said first end and said middle portion and a second curved part, said second curved part located between said middle portion and said second end.

7. The assembly according to claim 1, wherein said at least one separable portion extends in a direction generally parallel to said lead axis.

8. The assembly according to claim 1, wherein said first end has a first width, and said separable portion connected to said first end has a second width, said second width being less than said first width for said first end.

9. The assembly according to claim 1, wherein said separable portions extend transversely to said lead axis.

10. The assembly according to claim 9, wherein each separable portion interconnects adjacent leads and is connected to said first end of one of said leads.

11. A lead assembly comprising:
a connecting structure having a plurality of separable portions;
a plurality of leads, each said lead having a first end, a second end, a lead axis defined by said first end and said second end, and an offset portion disposed between said first end and said second end;
said offset portion being offset from said lead axis and adapted to be displaced downwardly with respect to a lead axis and bonded to a contact;
each lead being connected to said connecting structure and separable from the assembly by severing at least one of said separable portions; and
a bus element, said bus element interconnecting said separable portions.

12. The assembly according to claim 11, wherein said bus element comprises an elongate element extending transversely to said lead axes of said leads, the separable portions being attached to said bus element and are spaced apart from one another along said bus element.

13. The assembly according to claim 12, wherein each separable portion is connected to said first end of one of said leads.

14. The assembly according to claim 13, wherein each separable portion extends generally in said same direction as said lead axis.

15. A microelectronic component comprising:
a dielectric layer having a slot defined therein and a lead assembly overlying said dielectric layer;
said lead assembly comprising a plurality of leads, each said lead having an offset portion disposed between a first end and a second end, said offset portion being offset from a lead axis defined by said first end and said second end;
a connecting structure, said connecting structure connected to said first ends of said leads and interconnecting said leads; and
said lead assembly overlying said dielectric layer so that each offset portion is aligned with said slot.

16. The component according to claim 15, wherein said connecting structure comprises webs, said webs isolating said leads from said lead assembly.

17. The component according to claim 16, wherein said dielectric layer is constructed to allow access to said webs.

18. The component according to claim 17, wherein said dielectric layer has a plurality of apertures, each of said apertures being disposed in alignment with at least one of said webs.

19. The component according to claim 17, further comprising a window, said window being included with said dielectric element and aligned with said webs.

20. The component according to claim 16, wherein said slot comprises an elongate slot, said elongate slot being aligned with said webs as well as said offset portions.

21. The component according to claim 15, wherein said dielectric layer and said lead assembly are arranged so that said first ends of said leads are disposed at a first edge of said slot and said second ends of said leads are disposed at a second edge of said slot.

22. The component according to claim 15, wherein said offset portion comprises a middle portion, said middle portion being disposed between said first end and said second end of said leads.

23. The component according to claim 22, wherein said middle portion extends in a direction generally parallel to said lead axis.

24. The component according to claim 15, wherein said offset portion has a first curved part, said first curved part being located between said first end and said middle portion of said leads and a second curved part, said second curved part being located between said middle portion and said second end of said leads.

25. A method of forming a microelectronic assembly comprising:
providing a microelectronic component including a dielectric layer having a slot defined therein and a lead assembly overlying said dielectric layer, said lead assembly comprising a plurality of leads, each said lead having an offset portion, said offset portion located between a first end and a second end, said offset portion being offset from a lead axis defined by said first end and said second end, a connecting structure, said connecting structure connected to said first ends of said leads and including at least one separable portion interconnecting at least some of said leads;
said lead assembly overlying said dielectric layer so that each offset portion is aligned with said slot;
the microelectronic component including at least one aperture providing access to said at least one separable portion;
assembling the microelectronic component with a microelectronic element so that a first face of the microelectronic element faces the microelectronic component;
further including a plurality of contacts and connecting said offset portion of one of said leads to one of said plurality of contacts exposed at said first face; and
severing the connecting structure at said at least one separable portion so as to isolate said lead connected to said contact from said lead assembly.

26. The method according to claim 25, wherein said at least one separable portion comprises a plurality of webs interconnecting said leads.

27. The method according to claim 25, wherein the step of connecting includes forcing said offset portion toward one of said contacts.

28. The method according to claim 27, wherein said offset portions of a plurality of said leads are forced toward said contacts concurrently.

29. The method according to claim 28, wherein said each offset portion is desirably forced in a direction toward said first face and toward said lead axis.

30. The method according to claim 29, wherein said first end and second end are twisted as said offset portion is forced toward said contact.

31. The method according to claim 25, wherein said separable portions comprise webs for isolating said leads from said lead assembly.

32. The method according to claim 31, wherein said step of severing comprises advancing a tool carrying a blade into said at least one aperture to cut at least one of said webs.

33. The method according to claim 32, wherein the step of severing comprises using a tool carrying a plurality of blades to cut a plurality of said webs concurrently.

34. The method according to claim 25, wherein said step of assembling comprises arranging the microelectronic element and the microelectronic component so that said contacts are disposed between said first end and said second end, along said lead axis.

35. The method according to claim 34, wherein a flowable material is introduced into said slot, so as to surround said offset portion and said contact, after the step of bonding.

36. The method according to claim 34, further including at least one dielectric mass, wherein the step of assembling comprises disposing said at least one dielectric mass between said dielectric layer and the microelectronic element before the step of connecting.

37. The method according to claim 36, wherein said at least one dielectric mass is arranged to provide a standoff distance between said contacts and said leads, said leads having a length between said first end and said second end sufficient to span the standoff distance after the step of connecting.
